(19) United States
(12) Patent Application Publication
(10) Pub. No.: US 2024/0313172 A1
(43) Pub. Date: Sep. 19, 2024

(54) PRODUCTION METHOD AND OPTOELECTRONIC SEMICONDUCTOR CHIP

(71) Applicant: ams-OSRAM International GmbH, Regensburg (DE)

(72) Inventors: Gunnar Petersen, Regensburg (DE); Daniel Richter, Bad Abbach (DE)

(21) Appl. No.: 18/576,352

(22) PCT Filed: Jul. 5, 2022
(86) PCT No.: PCT/EP2022/068594

§ 371 Date: Jan. 3, 2024

(30) Foreign Application Priority Data
Jul. 9, 2021 (DE) 102021117801.0

(51) Int. Cl. H01L 33/50; H01L 21/66; H01L 33/00; H01L 33/46

(52) U.S. Cl. CPC H01L 33/508; H01L 33/0095; H01L 33/46; H01L 22/12; H01L 2933/0041; H01L 2933/0083

(57) ABSTRACT

A includes A) providing a wafer having a plurality of semiconductor regions for each of the optoelectronic semiconductor chips, B) applying a color conversion layer directly onto the wafer, the color conversion layer being applied continuously over the plurality of the semiconductor regions, C) performing a color correction so that a color conversion strength of the color conversion layer is locally reduced and D) separating the wafer into the semiconductor chips, wherein the steps are performed in the recited order, and wherein the step C) includes one of the following three possibilities: 1) creating a plurality of cracks and/or bubbles within the color conversion layer, 2) delaminating the color conversion layer locally directly from an emission side of the semiconductor regions, or 3) performing a thickness reduction of the color conversion layer from a top surface, wherein the color conversion layer includes at least one intermediate layer, and wherein the intermediate layer is a mirror layer.

### CROSS-REFERENCE TO RELATED APPLICATIONS

This patent application is a national phase filing under section 371 of PCT/EP2022/068594, filed Jul. 5, 2022, which claims the priority of German patent application 102021117801.0, filed Jul. 9, 2021, each of which is incorporated herein by reference in its entirety.

### TECHNICAL FIELD

A manufacturing method for optoelectronic semiconductor chips is provided. Furthermore, an optoelectronic semiconductor chip is provided.

### SUMMARY

Embodiments provide a manufacturing process for optoelectronic semiconductor chips that can be used to efficiently adjust the spectral radiation characteristics of the semiconductor chips.

According to at least one embodiment, the method comprises the step of providing a wafer with a plurality of semiconductor regions, each for one of the optoelectronic semiconductor chips. For this purpose, the wafer comprises in particular a carrier for a semiconductor layer sequence, wherein the semiconductor layer sequence is either already patterned to the semiconductor regions or is configured to be patterned to the semiconductor regions later in the process, for example, by etching, laser treatment and/or sawing.

The individual semiconductor regions can be nominally identical in construction, in particular within the manufacturing tolerances. The carrier can be a growth substrate of the semiconductor layer sequence or also a substitute carrier which replaces the growth substrate. Furthermore, it is possible that in some process steps the growth substrate is still present, which can then be replaced by the substitute carrier, so that in some process steps the substitute carrier is then present.

According to at least one embodiment, the process comprises the step of applying a color conversion layer to the wafer. Preferably, the color conversion layer is applied continuously over several, in particular over all, of the semiconductor regions. For example, the color conversion layer is applied by means of spraying and/or spin coating and/or printing and/or doctor blading and/or electrophoretically.

Preferably, the color conversion layer comprises one or more phosphors and/or one or more optical filter materials. In particular, the color conversion layer includes a color-changing component, such as inorganic phosphor particles or semiconductor quantum dots, and a matrix material in which the at least one color-changing component is embedded. The matrix material may be transparent in the relevant spectral range. Transparent means, for example, a transmittance of at least 90% or of at least 94% in the relevant spectral range. The term relevant spectral range refers in particular to a primary radiation generated by the semiconductor regions in operation and to a secondary radiation generated by the color conversion layer.

According to at least one embodiment, the method comprises the step of performing a color correction such that a color conversion strength of the color conversion layer is locally reduced. As a result of the color correction, the color conversion layer is, for example, locally removed and/or a formation of the color conversion layer is locally prevented and/or the color conversion layer is locally damaged. Preferably, the color conversion layer is not affected in places by performing the color correction.

According to at least one embodiment, the process comprises the step of separating the wafer into the semiconductor chips. In particular, the semiconductor layer sequence and/or the color conversion layer is divided, for example, by means of sawing and/or etching. As a result of the separation, the finished semiconductor chips can be produced directly or also a preliminary stage of the semiconductor chips can be produced, which still have to pass through at least one further process step.

In at least one embodiment, the method is for fabricating optoelectronic semiconductor chips and comprises at least the following steps:
A) providing a wafer having a plurality of semiconductor regions each for one of the optoelectronic semiconductor chips,
B) applying a color conversion layer to the wafer, the color conversion layer being applied continuously over a plurality of the semiconductor regions,
C) performing a color correction such that a color conversion strength of the color conversion layer is reduced in places, and
D) separating the wafer to form the semiconductor chips. In particular, the steps of the method are performed in the order of A)>B)>C)>D) and one of the following three possibilities applies: i) the step C) comprises: C4) creating a plurality of cracks and/or bubbles (44) within the color conversion layer (13), wherein the bubbles and/or cracks (44) are configured to reduce the color conversion strength of the color conversion layer (13) and at least some of the bubbles and/or cracks (44) are confined to an interior of the color conversion layer (13); ii) the step C) comprises: C5) peeling the color conversion layer locally from the semiconductor regions (12); iii) the step C) comprises: C6) performing a thickness reduction of the color conversion layer (13) from a top surface (30) of the color conversion layer (13) opposite to the semiconductor regions (12), wherein the color conversion layer (13) comprises at least one intermediate layer (45a, 45b), and the intermediate layer (45a, 45b) is a mirror layer.

In at least one embodiment, the method is for fabricating optoelectronic semiconductor chips and comprises at least the following steps:
A) providing a wafer having a plurality of semiconductor regions each for one of the optoelectronic semiconductor chips,
B) applying a color conversion layer to the wafer, the color conversion layer being applied continuously over a plurality of the semiconductor regions,
C) performing color correction so that a color conversion strength of the color conversion layer is reduced in places, and
D) separating the wafer to form the semiconductor chips. In particular, the steps of the method are carried out in the order A)>C)>B)>D), wherein step C) comprises: C7) depositing a plurality of displacement regions (46) on emission sides (20) of the semiconductor regions (12) facing the color conversion layer (13), and wherein in step B) the color conversion layer (13) is deposited with a flat top side (30) facing away from the semiconductor regions (12).

The manufacturing process described herein thus concerns a process for reworking or pre-processing semiconductor devices based on wafer level conversion.

In particular, the process described herein can achieve an improved product cost position due to a reduction of a reject, due to an improved color location adjustability, and an improvement of a component performance due to a more precise color location of an emitted radiation.

For LED devices that produce white light in the eye of the beholder, classically part of the light from a blue LED chip is converted to longer wavelengths, especially yellow light, via a phosphor conversion element. The combination of blue and yellow light thus gives the impression of white light.

The mere homogeneous application of a phosphor layer for the production of corresponding LED components leads to high costs, since, for example, the wavelength distribution of an emission in the blue spectral range across the finished processed LED wafer in combination with the conversion element without further color locus control results in a very broad color locus distribution of a mixed radiation, composed of the blue light of the LED chips and the yellow light of the phosphor. However, since a customer only accepts a very narrow color locus range, a so-called bin, either a high reject rate is produced or a great deal of effort has to be put into sorting and selectively combining LED chips and suitable conversion elements. Both are cost-intensive.

The basis of the process described here lies in particular in the targeted adaptation of the converter as a function of the local wafer wavelength and/or the measured color locus after application of the conversion layer. By the local adaptation of the conversion layer, the resulting component color locus can be shifted along a so-called converter line.

In particular, the following three cases are to be distinguished.
Selective removal of the conversion layer by masking: The process is based on a wafer to which the conversion layer is applied directly and over a large area. In this case, a conversion layer that is slightly too thick is selectively applied, which is then corrected locally to the desired color locus by processing. This is achieved, for example, by a mask adapted to the color locus distribution, which can be applied to the surface of the conversion layer in a wide variety of ways, for example as a photoresist, a metallic hard mask or a printed mask.

The mask itself preferably has openings of different sizes and/or densities. Thus, the conversion layer can be changed on a very small scale, both laterally and in the thickness of the layer. This is done by a material removal process. Many processes are available for this purpose, for example, wet chemical etching, dry etching or mechanical removal by particle bombardment. To remove impurities lying on the surface, such as fluorescent particles, and to smooth the surface, a cleaning step can be carried out afterwards. As a result, the color locus is individually and locally adjusted to the desired value.

Alternatively, material ablation can also take place without a mask, for example, by means of laser ablation or targeted local particle bombardment or liquid bombardment. In this case, the intensity, number and spacing of in particular pulsed laser shots can be used to achieve a desired ablation pattern. Afterwards, the surface can be cleaned and thus smoothed.
Pre-treatment of the LED wafer for chromaticity correction: In this case, an LED wafer without a conversion layer is assumed. Based on data from many wafers previously provided with a conversion layer, averaged local color locus dependencies are translated into a pattern, which is applied locally by means of a transparent and/or low-refractive index material. The low-refractive index material is, for example, a silicone, a siloxane or an epoxy. A conversion layer is then applied, for example, by means of lamination, also known as sheet lamination, by means of spray coating or by means of spraying and/or pressing, also known as molding. If necessary, a planarization step is also carried out. This changes the number of converter particles laterally by means of the thickness of the conversion layer and thus corrects the color location.
Post-treatment of the wafer by local delamination: It has been shown from defect analyses that local delamination between a conversion layer and a chip or also within the conversion layer leads to chromaticity shifts, especially due to total reflection. This can be exploited to carry out a chromaticity correction. In this case, a region of the conversion layer is heated strongly, for example by pulsed laser radiation, and thus a very small gas bubble is generated. The gas bubble leads to a shift in the color locus in the area of the gas bubble.

According to at least one embodiment, steps A), B), C) and D) of the process are performed in the order A)>B)>C)>D). That is, the color correction is performed after the color conversion layer has been applied to the wafer.

According to at least one embodiment, step C) comprises the following substep: C1) applying a mask, such as an etching mask, to the color conversion layer. Preferably, the mask comprises a plurality of holes or openings.

According to at least one embodiment, step C) comprises the following substep: C2) removing material from the color conversion layer through the holes in the mask so that the color conversion layer undergoes a thickness reduction in places. The material removal is, for example, an etching, such as a wet chemical or dry chemical etching, or an irradiation with particles or a liquid or electromagnetic radiation.

Preferably, the color conversion layer is not completely removed at any point, so that the color conversion layer can remain as a continuous, though-hole-free layer. Alternatively, the color conversion layer is completely removed in places. It is possible for the color conversion layer to undergo a reduction in thickness throughout or, preferably, for an original thickness of the color conversion layer to be retained in places.

According to at least one embodiment, step C) comprises the following substep: C3) removing the mask. The mask is removed, for example, chemically and/or thermally and/or mechanically. This preferably means that the mask is no longer present in the finished semiconductor chips.

According to at least one embodiment, steps C1), C2), C3) are performed in the order C1)>C2)>C3).

According to at least one embodiment, the thickness reduction of the color conversion layer is predetermined by a spatial distribution of the holes or openings. Alternatively or additionally, the thickness reduction is predetermined by a size of the holes and/or openings.

According to at least one embodiment, step C) comprises: C4) generating a plurality of cracks and/or bubbles preferably within the color conversion layer. The bubbles and/or cracks are particularly configured to reduce the color conversion strength of the color conversion layer. For example, the bubbles and/or the cracks create interfaces within the color conversion layer at which total internal reflection occurs. Thus, phosphor components of the color conversion layer, such as phosphor particles, can be locally shielded, at least in part, from primary radiation as generated in the semiconductor regions during operation. Alternatively or additionally, cracking or bubbling may be accompanied by local destruction or damage of the phosphor components.

According to at least one embodiment, some or all of the cracks and/or bubbles are confined to an interior of the color conversion layer. That is, the cracks and/or bubbles in question are confined to the interior of the color conversion layer and do not extend to outer boundary surfaces of the color conversion layer. This allows long-term stability and service life of the semiconductor chips to be increased.

According to at least one embodiment, step C) comprises:
C5) delaminating the color conversion layer in places from the semiconductor regions. In other words, the color conversion layer is delaminated in places from the semiconductor layer sequence. Areas where delamination occurs are preferably limited to an interior of the color conversion layer as viewed from above. That is, delaminated areas preferably do not extend to lateral boundary surfaces of the color conversion layer.

According to at least one embodiment, the step C) comprises:
C6) performing a thickness reduction of the color conversion layer from a top surface of the color conversion layer facing away from the semiconductor regions. This thickness reduction is preferably performed locally and without a mask. For example, laser ablation is performed locally or particle irradiation is performed locally.

According to at least one embodiment, the color conversion layer comprises one or more intermediate layers. Preferably, the at least one intermediate layer is free of a wavelength conversion component. In particular, the intermediate layer is free of phosphor particles. That is, the intermediate layer is not configured for wavelength conversion.

According to at least one embodiment, the intermediate layer is a mirror layer. In particular, the intermediate layer is a dichroic mirror. It is possible that several of the intermediate layers are present, which have spectral transmission edges from different each other. Alternatively or in addition to mirror layers, one or more absorption layers may also serve as intermediate layers. The absorption layers may have spectral absorption edges different from each other.

According to at least one embodiment, pulsed laser radiation is used in step C) to perform the color correction. It is possible that laser radiation of several different wavelengths of maximum intensity is used. For example, the laser radiation is near-infrared radiation, that is, for example, radiation with a wavelength of maximum intensity of at least 750 nm and/or of at most 2 μm.

According to at least one embodiment, steps A), B), C) and D) of the process are carried out in the sequence A)>C)>B)>D). This means that the color correction is carried out before the color conversion layer is applied.

According to at least one embodiment, step C) comprises:
C7) applying a plurality of displacement regions to emission sides of the semiconductor regions facing the color conversion layer. The displacement regions are preferably made of a material transparent to radiation which the semiconductor regions are configured to generate. In particular, the displacement regions are made of a silicon-containing material.

According to at least one embodiment, in step B) the color conversion layer is deposited with a flat top surface facing away from the semiconductor regions. The planar top surface may be created immediately with the deposition or may result from a planarization after the deposition. That is, the top surface may have a constant distance from the wafer carrier that remains constant throughout the color conversion layer. This applies, for example, with a tolerance of at most 10 μm or with a tolerance of at most 20 μm.

According to at least one embodiment, the displacement regions are lenticular, leaf-shaped or cuboid-shaped. Such shapes of the displacement regions are possible, for example, by applying the displacement regions by means of printing, such as three-dimensional printing. At least some of the displacement regions may be composed of several partial layers.

According to at least one embodiment, the method further comprises a step E), which is preferably performed before step C):
E) performing an analysis of the wafer across a plurality of the semiconductor regions with respect to anticipated emission characteristics of the semiconductor regions and/or the color conversion layer,
so that in step C) the color conversion strength is reduced based on the analysis. The analysis may actually refer to the wafer provided or to be provided with the color conversion layer. Alternatively or additionally, the analysis relates to a plurality of similar wafers previously processed or fabricated. That is, the analysis may refer to statistical and/or measured data of many similar wafers, so that the current wafer to be color corrected does not need to be analyzed, but could be analyzed.

According to at least one embodiment, a gradient with respect to the color conversion strength is generated in the color conversion layer per semiconductor region in step C). This means that the color correction can be specifically varied within a semiconductor chip and thus within a semiconductor region. Alternatively, a gradient is only generated at wafer level, so that individual semiconductor areas are not decisively color corrected.

According to at least one embodiment, in step C), an effective thickness of the color conversion layer of some or of all of the semiconductor regions is reduced by at least 2% or by at least 5% or by at least 8%. Alternatively or additionally, this thickness reduction is at most 15% or at most 30% or at most 50%. The effective thickness may be a geometric thickness or an optical thickness. In particular, the effective thickness indicates a thickness of a phosphor column accessible by or actually present at the semiconductor region in question. This thickness reduction preferably refers to a nominal thickness of the color conversion layer without color correction or before color correction.

Furthermore, an optoelectronic semiconductor chip is disclosed. In particular, the optoelectronic semiconductor chip is manufactured by a method as described in connection with one or more of the above embodiments. Features of the optoelectronic semiconductor chip are therefore also disclosed for the method, and vice versa.

In at least one embodiment of the optoelectronic semiconductor chip, the color conversion layer has a periodic thickness modulation. That is, the thickness modulation has, for example, a sinusoidal or sawtooth-like progression, in particular as viewed in cross-section perpendicular to an emission side of the semiconductor region in question. The thickness modulation relates in particular to the effective thickness of the color conversion layer.

According to at least one embodiment, the optoelectronic semiconductor chip includes a plurality of the displacement regions. Some or all of the displacement regions are completely surrounded by the respective semiconductor region of the semiconductor chip together with an associated portion of the color conversion layer.

In the following, a method described herein and an optoelectronic semiconductor chip described herein are explained in more detail with reference to the drawing on the basis of exemplary embodiments. Identical reference signs indicate identical elements in the individual figures. However, no references to scale are shown, rather individual elements may be shown exaggeratedly large for better understanding.

### BRIEF DESCRIPTION OF THE DRAWINGS

In the figures:

FIGS. 1 to 4 and 6 to 10 are schematic sectional views of steps of an exemplary embodiment of a method for manufacturing optoelectronic semiconductor chips described herein;

FIG. 5 is a schematic top view of the method step of FIG. 4;

FIGS. 11 and 12 are schematic top views of wafers for exemplary embodiments of methods for manufacturing optoelectronic semiconductor chips described herein;

FIGS. 13 to 15 are schematic sectional views of steps of an exemplary embodiment of a method for manufacturing optoelectronic semiconductor chips described herein;

FIGS. 16 to 19 are schematic sectional views of steps of an exemplary embodiment of a method for manufacturing optoelectronic semiconductor chips described herein;

FIGS. 20 to 23 are schematic sectional views of steps of an exemplary embodiment of a method for manufacturing optoelectronic semiconductor chips described herein;

FIGS. 24 to 26 are schematic sectional views of steps of an exemplary embodiment of a method for manufacturing optoelectronic semiconductor chips described herein;

FIG. 27 is a schematic top view of the method step of FIG. 26; and

FIG. 28 is a schematic sectional view of a step of an exemplary embodiment of a method for manufacturing optoelectronic semiconductor chips described herein.

### DETAILED DESCRIPTION OF ILLUSTRATIVE EMBODIMENTS

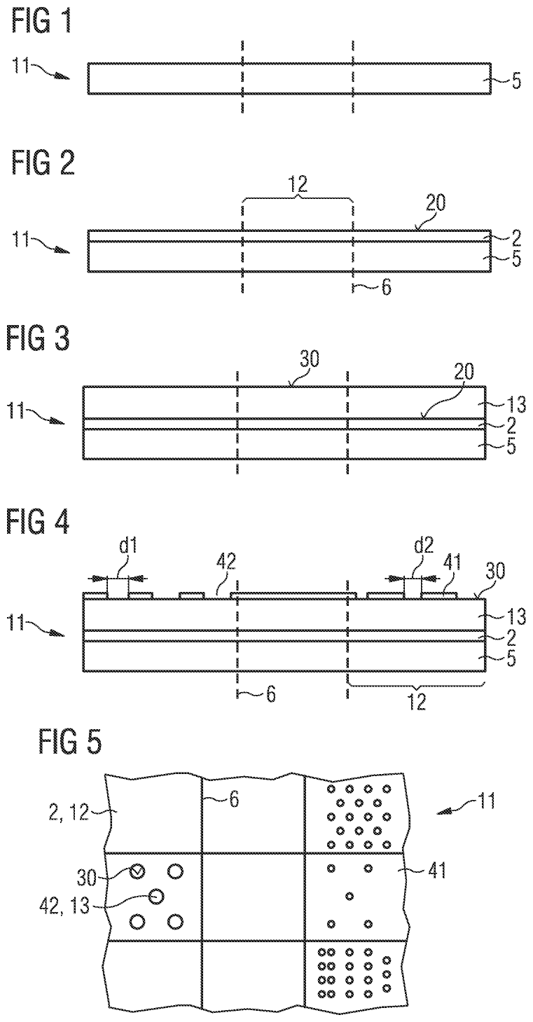

FIGS. 1 to 10 illustrate an embodiment of a manufacturing process for optoelectronic semiconductor chips 1 using a wafer 11. According to FIG. 1, a carrier 5 is provided. The carrier 5 is, for example, made of silicon or of sapphire.

According to FIG. 2, a semiconductor layer sequence 2 is grown on the carrier 5. The semiconductor layer sequence 2 can be grown continuously and coherently.

The semiconductor layer sequence 2 has at least one active region which, in operation, is configured to generate radiation by means of electroluminescence. The semiconductor layer sequence is preferably based on a III-V compound semiconductor material. The semiconductor material is, for example, a nitride compound semiconductor material such as AlₙIn₁₋ₙ₋ₘGaₘN or a phosphide compound semiconductor material such as AlₙIn₁₋ₙ₋ₘGaₘP or also an arsenide compound semiconductor material such as AlₙIn₁₋ₙ₋ₘGaₘAs or such as AlₙGaₘIn₁₋ₙ₋ₘAsₖP₁₋ₖ, where in each case 0≤n≤1, 0≤m≤1 and n+m≤1 as well as 0≤k<1. For example, it applies 0<n≤0.8, 0.4≤m<1 and n+m≤0.95 as well as 0<k≤0.5 to at least one layer or to all layers of the semiconductor layer sequence. In this context, the semiconductor layer sequence may comprise dopants as well as additional components. For simplicity, however, only the essential constituents of the crystal lattice of the semiconductor layer sequence, that is, Al, As, Ga, In, N or P, are indicated, even if these may be partially replaced and/or supplemented by small amounts of additional substances. Preferably, the semiconductor layer sequence 2 is based on the material system AlₙIn₁₋ₙ₋ₘGaₘN.

A emission side 20, which is provided for radiation emission out of the semiconductor layer sequence 2, faces away from the carrier 5.

The semiconductor layer sequence 2 is configured to be divided later along separation lines 6 into a plurality of semiconductor regions 12, so that one of the semiconductor regions 12 is present per semiconductor chip 1 to be manufactured. This division is not illustrated in FIG. 2, but may already be present in the step of FIG. 2. That is, gaps may be present between adjacent semiconductor regions 12. The semiconductor regions 12 may all have the same structure within the manufacturing tolerances.

Other components directly on the semiconductor regions 12, such as electrical contact structures or passivation layers, are not drawn for ease of illustration. For example, electrical contact structures or passivation layers are present as described in FIG. 2A, 2B or 2C of US 2018/0248091 A1, see also paragraphs 71 and 72 therein. The disclosure content of this document with respect to FIGS. 2A, 2B and 2C and paragraphs 71 and 72 is incorporated by reference.

FIG. 3 shows that a color conversion layer 13 is applied to the semiconductor regions 12. A top surface 30 of the color conversion layer 13 facing away from the carrier 5 is preferably planar. This means that the color conversion layer 13 is applied to the semiconductor layer sequence 2 over a large area, for example, by means of spray coating.

The color conversion layer 13 can be applied in two stages, so that a material application can be followed by planarization. For example, the color conversion layer 13 is composed of a transparent matrix material, such as a silicone or a siloxane or a glass, and phosphor particles embedded therein, not drawn. For example, the phosphor particles or some of the phosphor particles are made of YAG:Ce. It is possible that the phosphor particles have an average diameter of at least 2 μm and/or at most 20 μm.

A thickness of the color conversion layer 13 is, for example, at least 15 μm and/or at most 150 μm, for example between 20 μm and 80 μm inclusive. A volume fraction of phosphor particles in the color conversion layer 13 is, for example, at least 25% and/or at most 75%.

According to FIG. 4, an etching mask 41 is applied to the top surface 30 of the color conversion layer 13. The etching mask 41 is, for example, a structured photoresist or a hard mask.

The etching mask 41 has holes 42, see also FIG. 5. The holes 42 have different diameters d1, d2. A subsequent material removal from the color conversion layer 13 can be adjusted via a density and via a size of the holes 42.

This is schematically illustrated in various constellations in FIG. 5. For example, a size of the holes 42 can be varied for the same arrangement of the holes 42, see the middle row in FIG. 5. Furthermore, an arrangement density of the holes 42 can be varied, see the right column in FIG. 5. There can be a uniform density of the holes 42 per semiconductor region 12 or there can be a specific area density gradient within a semiconductor region 12, see the semiconductor region 12 at the bottom right in FIG. 5. It is also possible that some of the semiconductor regions 12 are completely covered by the etching mask 41, that is, are free of the holes 42.

For example, the holes 42 have a diameter d1, d2 of at least 5 μm. Alternatively or additionally, the diameter d1, d2 is at most 50 μm. In particular, the diameter d1, d2 is between 10 μm and 30 μm inclusive. For example, a minimum distance between adjacent holes 42 is at least 5 μm and/or at most 100 μm. The holes 42, which may be circular or polygonal in shape, are present, for example, in a rectangular pattern or in a hexagonal pattern.

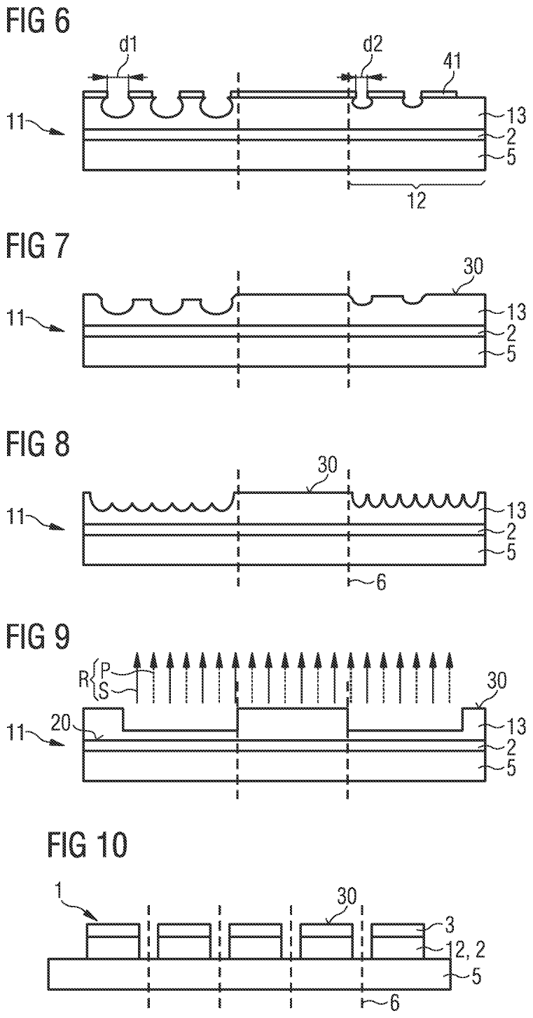

In FIG. 6 it is shown that by means of a removal agent 48, such as an etchant, the color conversion layer 13 is partially removed. The etchant 48 is, for example, a liquid. Alternatively, a mechanical abrasive material removal process may be used. In this case, the removal agent 48 may be formed by particles, not drawn.

Due to the structure of the etching mask 41, preferably a different degree of material removal occurs for different semiconductor regions 12, see FIG. 7.

According to FIG. 7, the surface structure of the color conversion layer 13 resulting from the material removal is periodic but comparatively coarse. For example, seen in cross-section, a periodicity of the surface structure is at least 20 μm and/or at most 200 μm. In contrast, FIG. 8 shows that the periodicity of the surface structure can also be much finer and, for example, is at least 1 μm and/or at most 20 μm.

In the optional step shown in FIG. 9, the surface structure of the top surface 30 created by the material removal is smoothed. This allows the top surface 30 to be flat in the individual semiconductor regions and oriented parallel to the respective emission side 20.

In addition, it is illustrated in FIG. 9 that a primary radiation P is generated by the semiconductor regions 12 during operation, which mixes with a secondary radiation S to form a total emitted radiation R, such as white light. A local thickness of the color conversion layer 13 can be used to adjust the amount of primary radiation P that is converted to the secondary radiation S, and thus the resulting chromaticity coordinate of the radiation R.

In the step of FIG. 10 it is shown that the color conversion layer 13 and optionally the semiconductor layer sequence 2, if not already divided in the step of FIG. 2, are separated to form areas for the individual semiconductor chips 1. This results in phosphor layers 3 on the respective separate semiconductor regions 12, the phosphor layers 3 having different effective thicknesses. To simplify the illustration, an internal structure of the phosphor layers 3 is not drawn in FIG. 10.

The carrier 5 can also be affected by the separation process and, in contrast to the illustration in FIG. 10, can also be divided. Alternatively, the carrier 5 remains as a whole.

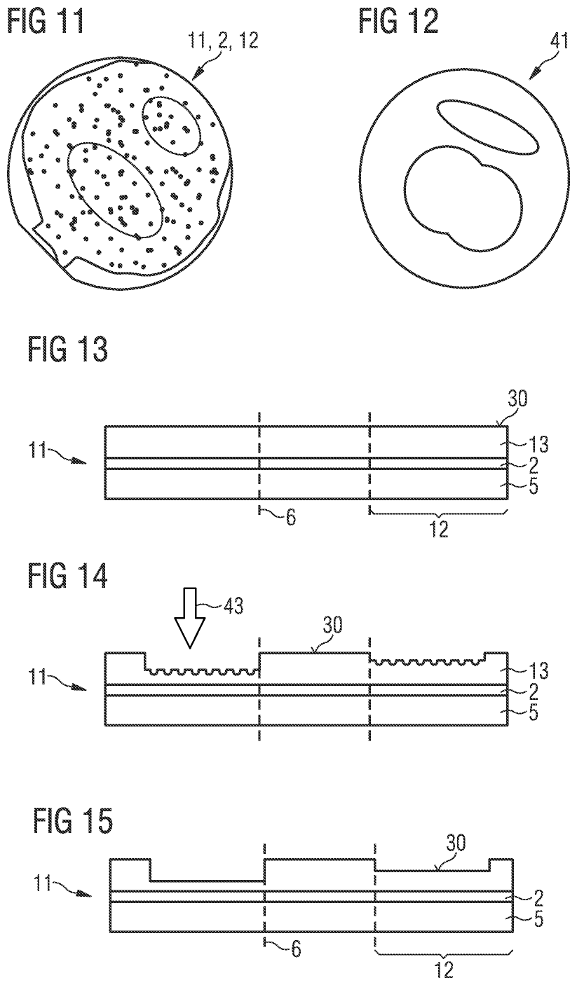

FIG. 11 shows a wafer 11 with the semiconductor layer sequence 2 and the semiconductor regions 12. Light and dark areas schematically represent different emission wavelengths of the semiconductor regions 12. The distribution of emission wavelengths may be typical across many wafers 11, so that an individual measurement of each wafer 11 is not mandatory. Alternatively, each wafer 11 can be measured, for example using photoluminescence, to determine the distribution of emission wavelengths across the wafer 11.

Based on the distribution of the emission wavelengths, the required mask 41 for processing the color conversion layer 13 can be determined, see FIG. 12. In FIG. 12, the mask 41 is shown simplified with only two different areas, whereby a finer gradation can be present with regard to the material removal to be achieved, as illustrated in particular in FIGS. 4 to 6.

A thickness of the color conversion layer 13 is preferably selected such that a target color locus can be achieved for each of the semiconductor regions 12. In particular by means of the mask 41, the color conversion layer 13 is then thinned locally so that the target color location is reached, depending on the locally present emission wavelengths of the semiconductor regions 12.

In all other respects, the comments on FIGS. 1 to 10 apply in the same way to FIGS. 11 and 12, and vice versa.

FIGS. 13 to 15 show a further example of the manufacturing process. According to FIG. 13, the wafer 11 is provided with the semiconductor layer sequence 2 and the still constant thickness color conversion layer 13, analogous to FIGS. 1 to 3.

According to FIG. 14, material is removed from the color conversion layer 13 by means of laser ablation, so that a pulsed laser beam 43 is irradiated onto the color conversion layer 13. As in the process of FIGS. 1 to 10, the amount of material to be ablated may be predetermined individually for each semiconductor region 12. The step of FIG. 14 is preferably performed without an additional mask, unlike in FIGS. 1 to 10.

In the optional step of FIG. 15, the top surface 30 can be smoothed and/or cleaned. This can result in a smooth, flat top surface 30 of the color conversion layer 13 per semiconductor area 12.

In all other respects, the comments on FIGS. 1 to 12 apply in the same way to FIGS. 13 to 15, and vice versa.

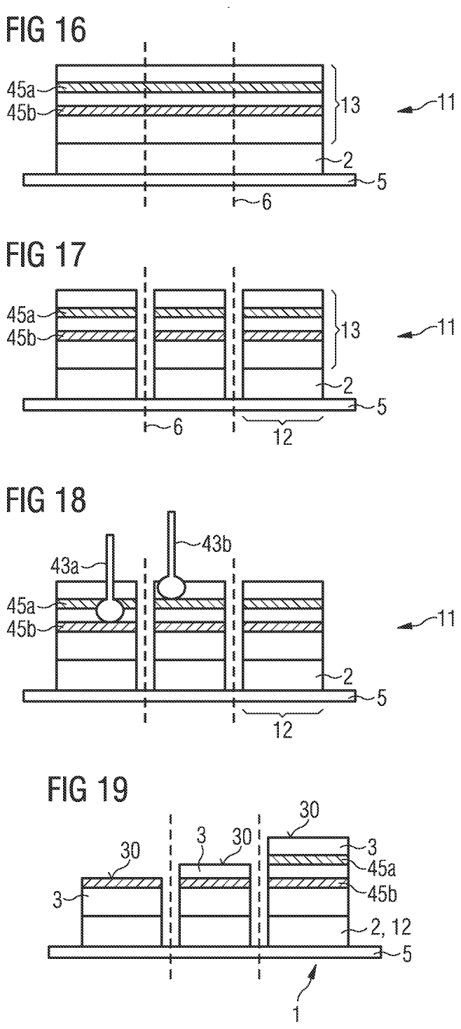

In the method of FIGS. 16 to 19, the color conversion layer 13 comprises a plurality of intermediate layers 45a, 45b. The intermediate layers 45a, 45b are mirror layers. For example, the intermediate layers 45a, 45b each are Bragg mirrors having different reflection edges. Below a wavelength corresponding to the reflection edge, the associated mirror layer is transparent and above it is reflective.

In the direction towards the semiconductor layer sequence 2, the reflection edges can decrease, that is, shift towards smaller wavelengths. For example, the reflection edge of layer 45a is at 1100 nm and that of layer 45b is at 900 nm. The intermediate layers 45a, 45b are preferably transparent in the visible spectral range, so that the reflective layers have no or no significant influence on an operation of the finished semiconductor chips.

In the step of FIG. 17, a separation is performed through the semiconductor layer sequence 2 and through the color conversion layer 13, whereby the carrier 5 is preferably preserved. The step of FIG. 17 can also be carried out at another stage of the process, see the process of FIGS. 1 to 10, and correspondingly vice versa.

FIG. 18 shows that two laser beams 43a, 43b are used to partially ablate the color conversion layer 13. For example, the laser beam 43a has a wavelength of 920 nm and the laser beam 43b has a wavelength of 1200 nm. Thus, with the aid of the intermediate views 45a, 45b, specific layers of the color conversion layer 13 can be selectively ablated by means of the laser beams 43a, 43b. The laser beams 43a, 43b are, for example, ns pulses.

In each case, there may be more than two intermediate layers or only one of the intermediate layers. As an alternative to mirror layers, the intermediate layers can also be designed as absorbent layers, in particular with different band edges.

FIG. 19 shows the resulting semiconductor chips 1, wherein the semiconductor chips 1 comprise phosphor layers 3 of different thicknesses. The top surfaces 30 may be formed by a phosphor-containing region of the phosphor layers 3 in case the intermediate layers 45a, 45b are peeled off. Alternatively, it is equally possible that the top surfaces 30 or at least some of the top surfaces 30 are formed by the intermediate layers 45a, 45b.

In all other respects, the comments on FIGS. 1 to 15 apply in the same way to FIGS. 16 to 19, and vice versa.

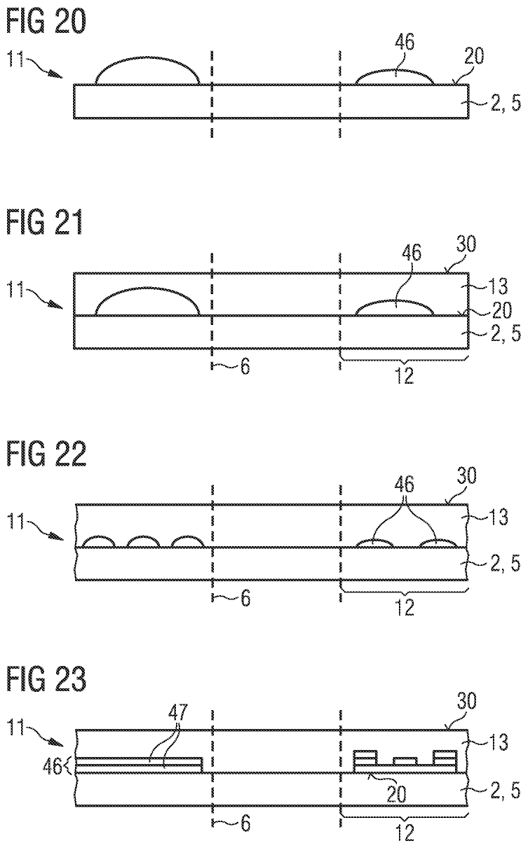

In the process of FIGS. 20 and 21, a plurality of displacement regions 46 are created prior to the deposition of the color conversion layer 13. The displacement regions 46 are preferably made of a material transparent to the primary radiation generated in the semiconductor regions 12, such as a silicone, a siloxane or a glass. In particular, the displacement regions 46 are applied according to an analysis as explained in connection with FIGS. 11 and 12.

FIG. 21 shows that the color conversion layer 13 is then applied over the displacement regions 46. The top surface 30 is preferably flat and in particular parallel to the emission side 20. The displacement regions 46 thus adjust the thickness of the color conversion layer 13 atop the respective semiconductor regions 12.

In all other respects, the comments on FIGS. 1 to 19 apply in the same way to FIGS. 20 and 21, and vice versa.

FIG. 22 shows a variant of the displacement regions 46. In contrast to FIG. 21, there are several displacement regions 46 for each semiconductor region 12 that is to be color corrected. As in FIG. 5, the size and distribution of the displacement regions 46 can be used to set the extent of the color correction.

In all other respects, the comments on FIGS. 1 to 21 apply in the same way to FIG. 22, and vice versa.

FIG. 23 illustrates that the displacement regions 46 can be composed of several partial layers 47. This also allows layered, that is, plane-parallel or almost plane-parallel, or cuboid displacement regions 46 to be realized. In the left third of FIG. 23, it is shown that the partial layers 47 can be congruent. Similar to the intermediate layers 45a, 45b of FIGS. 16 to 19, this makes it possible to produce specific, fixed thicknesses of the displacement regions 46.

The right third of FIG. 23 shows that the partial layers 47 are not congruent. Thus, different numbers of the partial layers 47 can be present at different locations on the emission side 20. In this way, concave displacement regions 46 can also be produced and not only convex displacement regions 46, as for example in FIG. 21.

For example, a thickness of the displacement regions 46, as shown in FIGS. 20 to 23, is each at least 5% and/or at most 30% of a maximum thickness of the color conversion layer 13.

In all other respects, the comments on FIGS. 1 to 22 apply in the same way to FIG. 23, and vice versa.

The displacement regions 46 can be created, in addition to via structured application, such as imprinting, via a structuring process, such as photolithography. For example, to this end, the displacement regions 46 are created from a material, such as a photoresist, or a mask, such as a photoresist, is used to pattern the displacement regions 46. That is, the displacement regions 46 may be generated lithographically. Likewise, lithographic patterning may be used in any other embodiments.

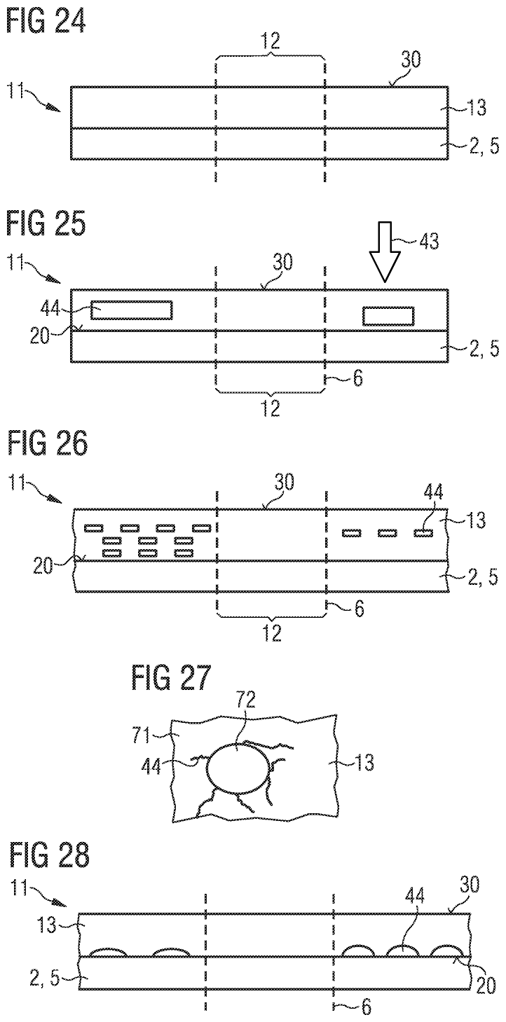

In the process of FIGS. 24 and 25, the color conversion layer 13 is again first applied to the semiconductor regions 12, see FIG. 24.

Thereafter, see FIG. 25, for example, a plurality of cavities 44 are created within the color conversion layer 13 by means of the pulsed laser radiation 43. The cavities 44 are, for example, thin areas that are gas-filled, for example filled with a gas that enters the color conversion layer 13 from the outside or that is created when the color conversion layer 13 is irradiated.

The cavities 44 locally reduce an optical coupling of the color conversion layer 13 to the semiconductor regions 12. This allows the effective thickness of the color conversion layer 13 to be adjusted locally.

Preferably, the cavities 44 or at least some of the cavities 44 are placed completely within the color conversion layer 13. It is possible, in particular by means of a position of a focal plane of the laser radiation 43, to create the cavities 44 aligned, for example, parallel to the emission side 20, at different distances from the emission side 20. By the distance of the cavities 44 from the emission side 20, a conversion efficiency and/or a directionality of an emission can be adjusted.

In all other respects, the comments on FIGS. 1 to 23 apply in the same way to FIGS. 24 and 25, and vice versa.

FIG. 26 illustrates that there can be many small cavities 44 per semiconductor region 12, analogous to FIGS. 4 and 5 with respect to the mask 41. There can also be several layers of cavities 44 on top of each other, see the left third in FIG. 26. The cavities 44 of the individual layers can be arranged congruently on top of each other as seen in plan view of the emission side 20, or laterally offset from each other, or mixtures thereof.

In all other respects, the comments on FIGS. 1 to 25 apply in the same way to FIG. 26, and vice versa.

In FIG. 27, a detailed view around a phosphor particle 72 located in a matrix material 71 of the color conversion layer 13 is shown. Here, a large number of cracks appear around the phosphor particle 72 due to the laser irradiation, forming the voids. The cracks are preferably only thin, for example, at most 1 μm thick.

The cracks form a plurality of optical interfaces around the phosphor particle 72, so that primary radiation from the associated semiconductor region 12 is guided around the phosphor particle 72 to a comparatively large extent. In this way, a conversion efficiency in the color conversion layer 13 can be reduced. Since the cracks have only small geometric dimensions, the top surface 30 can remain flat. That is, the voids 44 do then not cause local curvature of the top surface 30.

The areas identified as cavities 44 in FIGS. 25 and 26 may be areas where such cracks are present, as illustrated in FIG. 27. That is, the voids 44 need not be continuous voids or cavities, but may be areas of high crack density around the phosphor particles 72. For example, at least 10 cracks per mm³ or at least 100 cracks per mm³ are present in the cavities 44.

In all other respects, the comments on FIGS. 1 to 26 apply in the same way to FIG. 27, and vice versa.

In the process of FIG. 28, after the color conversion layer 13 has been generated, the cavities 44 are created directly on the emission side 20. This means that there is then no material of the color conversion layer 13 between the cavities 44 and the associated semiconductor regions 12. In other words, a local delamination of the color conversion layer 13 from the emission side 20 takes place. This delamination is achieved in particular by means of a laser irradiation, not drawn.

For an extent of color correction, a size and a distribution of the areas where delamination is present can be set, analogous to FIGS. 4 and 5.

In all other respects, the comments on FIGS. 1 to 27 apply in the same way to FIG. 28, and vice versa.

The components shown in the figures preferably follow one another in the sequence indicated, in particular directly one after the other, unless otherwise described. Components not touching each other in the figures are preferably spaced apart. Insofar as lines are drawn parallel to one another, the associated surfaces are preferably likewise aligned parallel to one another. Furthermore, the relative positions of the drawn components to each other are correctly reproduced in the figures, unless otherwise specified.

The invention described herein is not limited by the description based on the embodiments. Rather, the invention encompasses any new feature as well as any combination of features, which in particular includes any combination of features in the patent claims, even if this feature or combination itself is not explicitly stated in the patent claims or embodiments.

1.-17. (canceled)

18. A method for manufacturing optoelectronic semiconductor chips, the method comprising the steps of:
A) providing a wafer having a plurality of semiconductor regions for each of the optoelectronic semiconductor chips;
B) applying a color conversion layer directly onto the wafer, the color conversion layer being applied continuously over the plurality of the semiconductor regions;
C) performing a color correction so that a color conversion strength of the color conversion layer is locally reduced; and
D) separating the wafer into the semiconductor chips,
wherein the steps are performed in the recited order, and
wherein the step C) comprises one of the following three possibilities:
1) creating a plurality of cracks and/or bubbles within the color conversion layer, wherein the bubbles and/or cracks are configured to reduce the color conversion strength of the color conversion layer and at least some of the bubbles and/or cracks are confined to an interior of the color conversion layer,
2) delaminating the color conversion layer locally directly from an emission side of the semiconductor regions, or
3) performing a thickness reduction of the color conversion layer from a top surface of the color conversion layer facing away from the semiconductor regions, wherein the color conversion layer comprises at least one intermediate layer, and wherein the intermediate layer is a mirror layer.

19. The method according to claim 18, wherein the step C) further comprises:
applying an etching mask having a plurality of holes onto the color conversion layer,
etching the color conversion layer through the holes in the etching mask so that the color conversion layer undergoes the thickness reduction in places, and
removing the etching mask.

20. The method according to claim 19, wherein the thickness reduction of the color conversion layer is predetermined by a spatial distribution of the holes and/or by a size of the holes.

21. The method according to claim 18,
wherein the step C) further comprises creating the plurality of cracks and/or bubbles within the color conversion layer,
wherein the bubbles and/or cracks are configured to reduce the color conversion strength of the color conversion layer, and
wherein at least some of the bubbles and/or cracks are confined to the interior of the color conversion layer.

22. The method according to claim 18, wherein the step C) comprises delaminating the color conversion layer locally from the semiconductor regions.

23. The method according to claim 22, wherein areas where delamination occurs are limited to the interior of the color conversion layer as viewed from above so that delaminated areas do not extend to lateral boundary surfaces of the color conversion layer of the respective optoelectronic semiconductor chip.

24. The method according to claim 18, wherein the step C) comprises performing the thickness reduction of the color conversion layer from the top surface of the color conversion layer facing away from the semiconductor regions.

25. The method according to claim 24, wherein the color conversion layer comprises the at least one intermediate layer, and wherein the intermediate layer is the mirror layer.

26. The method according to claim 18, wherein the step C) comprises using a pulsed laser radiation to perform the color correction.

27. The method according to claim 18, further comprising a step E) prior to the step C), wherein the step E) comprises performing an analysis of the wafer across the plurality of the semiconductor regions with respect to anticipated emission characteristics of the semiconductor regions and/or of the color conversion layer such that in the step C) the color conversion strength is reduced based on the analysis.

28. The method according to claim 18, wherein the step C) further comprises generating a gradient in the color conversion layer per semiconductor region with respect to the color conversion strength.

29. The method according to claim 18, wherein the step C) further comprises reducing, for at least some of the semiconductor regions, an effective thickness of the color conversion layer by at least 5% and by at most 30%, relative to a nominal thickness of the color conversion layer without the color correction.

30. A method for manufacturing optoelectronic semiconductor chips, the method comprising the step of:
A) providing a wafer having a plurality of semiconductor regions for each of the optoelectronic semiconductor chips;
B) applying a color conversion layer to the wafer, the color conversion layer being applied continuously over a plurality of the semiconductor regions;
C) performing a color correction so that a color conversion strength of the color conversion layer is locally reduced; and
D) separating the wafer into the semiconductor chips,
wherein the steps are performed in the recited order,
wherein the step C) comprises applying a plurality of displacement regions to emission sides of the semiconductor regions facing the color conversion layer,
wherein the step B) comprises applying the color conversion layer on a top surface facing away from the semiconductor regions and being flat, and
wherein at least some of the displacement regions are composed of a plurality of partial layers.

31. The method according to claim 30,
wherein the displacement regions are lens-shaped, sheet-shaped, or cuboid-shaped, and
wherein the displacement regions are of a material transparent to radiation that the semiconductor regions are configured to generate.

32. The method according to claim 30, wherein different numbers of the partial layers are present at different locations on the emission sides.

33. The method according to claim 30, further comprising a step E) prior to the step C), wherein the step E comprises performing an analysis of the wafer across the plurality of the semiconductor regions with respect to anticipated emission characteristics of the semiconductor regions and/or of the color conversion layer such that in the step C) the color conversion strength is reduced based on the analysis.

34. The method according to claim 30, wherein the step C) comprises generating a gradient in the color conversion layer per semiconductor region with respect to the color conversion strength.

35. The method according to claim 30, wherein the step C) comprises reducing, for at least some of the semiconductor regions, an effective thickness of the color conversion layer by at least 5% and by at most 30%, relative to a nominal thickness of the color conversion layer without the color correction.

36. The optoelectronic semiconductor chip fabricated by the method according to claim 30, wherein the color conversion layer of the semiconductor chip has a periodic thickness modulation.

37. The optoelectronic semiconductor chip according to claim 36, wherein the semiconductor chip comprises a plurality of the displacement regions, each completely surrounded by the semiconductor region of the semiconductor chip together with an associated portion of the color conversion layer.
